(19) United States
(12) Patent Application Publication
(10) Pub. No.: US 2022/0238667 A1
(43) Pub. Date: Jul. 28, 2022

(54) SEMICONDUCTOR STRUCTURE AND FORMING METHOD THEREOF

(71) Applicants: Semiconductor Manufacturing International (Shanghai) Corporation, Shanghai (CN); Semiconductor Manufacturing International (Beijing) Corporation, Beijing (JP)

(72) Inventor: Nan WANG, SHANGHAI (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 17/574,904

(22) Filed: Jan. 13, 2022

(30) Foreign Application Priority Data
Jan. 26, 2021 (CN) 202110105306.3

(51) Int. Cl. H01L 29/417; H01L 29/40

(52) U.S. Cl. CPC H01L 29/41775; H01L 29/401

(57) ABSTRACT

Disclosed are a semiconductor structure and a forming method thereof. In one form, a semiconductor structure includes: a base; gate structures arranged discretely on the base, including gate contact regions used for contact with gate plugs; source/drain doped regions, including source/drain contact regions and source/drain connection regions; dielectric structure layers, located on the base on sides of the gate structures and covering the source/drain doped regions and the gate structures; source/drain contact structures, being in contact with the source/drain doped regions, where the source/drain contact structures are an integrated structure, and include source/drain plugs penetrating dielectric structure layers of the source/drain contact regions and source/drain contact layers located in dielectric structures of the source/drain connection regions, top surfaces of the source/drain contact layers are lower than top surfaces of the source/drain plugs, and the source/drain contact structures and the dielectric structure layers enclose spaced openings; spaced dielectric layers, filling the spaced openings; and gate plugs, located on tops of the gate structures in the gate contact regions and in contact with the gate structures. The source/drain contact structures of implementations of the present disclosure are an integrated structure, which improves performance of electrical connection between the source/drain plugs and the source/drain contact layers.

### RELATED APPLICATIONS

The present application claims priority to Chinese Patent Appln. No. 202110105306.3, filed Jan. 26, 2021, the entire disclosure of which is hereby incorporated by reference.

### BACKGROUND

### Technical Field

Embodiments and implementations of the present disclosure relate to the field of semiconductor manufacturing, and in particular, to a semiconductor structure and a forming method thereof.

### Related Art

With the continuous development of integrated circuit manufacturing technologies, requirements for the integration and performance of integrated circuits have become increasingly high. To improve integration and reduce costs, critical dimensions of components are continuously reduced, and circuit densities in integrated circuits are increasingly large. Such a development makes a surface of a wafer unable to provide an enough area to fabricate required interconnect lines.

To meet the requirements of the interconnect lines after the critical dimensions are reduced, conduction between different metal layers or a metal layer and a base is currently realized through an interconnect structure. The interconnect structure includes interconnect lines and contact hole plugs formed in contact openings. The contact hole plugs are connected to a semiconductor device, and the interconnect lines realize connections between the contact hole plugs, thereby forming circuits. Contact hole plugs in a transistor structure include gate contact hole plugs located on a surface of a gate structure and used for connecting the gate structure to external circuits, and further include source/drain contact hole plugs located on a surface of a source/drain doped region and used for connecting the source/drain doped region to the external circuits.

At present, to further reduce an area of a transistor, a contact over active gate (COAG) process is introduced. Compared with the conventional process in which gate contact hole plugs are located above gate structures of an isolation region, gate contact hole plugs can be made above gate structures of an active area (AA) in the COAG process, thereby further saving an area of a chip. However, it continues to be desirable to improve a performance of semiconductor structures.

### SUMMARY

To address the problems described above, embodiments and implementations of the present disclosure provide a semiconductor structure and a forming method thereof, to enhance performance of a semiconductor structure.

To address the foregoing problems, embodiments and implementations of the present disclosure provide a semiconductor structure. In one form, a semiconductor structures includes: a base; a plurality of gate structures arranged discretely on the base, where the gate structures include gate contact regions configured to come in contact with gate plugs; source/drain doped regions, located in the base on two sides of the gate structures, where the source/drain doped regions include source/drain contact regions configured to come in contact with source/drain plugs, and remaining regions of the source/drain doped regions are configured for use as source/drain connection regions; dielectric structure layers, located on the base on sides of the gate structures and covering the source/drain doped regions, where the dielectric structure layers further cover tops of the gate structures; source/drain contact structures, being in contact with the source/drain doped regions, where the source/drain contact structures are an integrated structure, and include source/drain plugs penetrating dielectric structure layers of the source/drain contact regions and source/drain contact layers located in dielectric structures of the source/drain connection regions, top surfaces of the source/drain contact layers are lower than top surfaces of the source/drain plugs, and the source/drain contact structures and the dielectric structure layers enclose spaced openings; spaced dielectric layers, filling the spaced openings; and gate plugs, located on tops of the gate structures in the gate contact regions and in contact with the gate structures.

Embodiments and implementations of the present disclosure further provide a forming method of a semiconductor structure. In one form, a method includes: providing a base, where a plurality of discrete gate structures are formed on the base, where the gate structures include gate contact regions used for contact with gate plugs, source/drain doped regions are formed in the base on two sides of the gate structures, the source/drain doped regions include source/drain contact regions used for contact with source/drain plugs, remaining regions of the source/drain doped regions are used as source/drain connection regions, and bottom dielectric layers are formed on the base on sides of the gate structures and cover the source/drain doped regions; forming top dielectric layers on the bottom dielectric layers; forming source/drain contact materials penetrating the bottom dielectric layers on tops of the source/drain doped regions and the top dielectric layers, to be in contact with the source/drain doped regions; removing partial thicknesses of the source/drain contact materials located in the source/drain connection regions, where remaining source/drain contact materials located in the source/drain connection regions are used as source/drain contact layers, the source/drain contact materials located in the source/drain contact regions are used as source/drain plugs, the source/drain plugs and the source/drain contact layers are used for forming source/drain contact structures, and the source/drain contact structures enclose spaced openings with the bottom dielectric layers and the top dielectric layers; filling the spaced openings with spaced dielectric layers; and forming, after forming the spaced dielectric layers, gate plugs penetrating the top dielectric layers above the gate contact regions, to be in contact with tops of the gate structures in the gate contact regions.

Compared with existing technologies, technical solutions of embodiments and implementations of the present disclosure have at least the following advantages.

In forms of a semiconductor structure provided in embodiments and implementations of the present disclosure, the source/drain contact structures are an integrated structure, and include source/drain plugs penetrating dielectric structure layers of the source/drain contact regions and source/drain contact layers located in dielectric structures of the source/drain connection regions, and top surfaces of the source/drain contact layers are lower than top surfaces of the source/drain plugs. The source/drain contact structures are an integrated structure, which reduces resistances of the source/drain plugs and the source/drain contact layers, and contact resistances between the source/drain plugs and the source/drain contact layers, and correspondingly improves performance of electrical connection between the source/drain plugs and the source/drain contact layers. Therefore, a back-end-of-line resistance capacitance (RC) delay is alleviated, power consumption is reduced, and a circuit response speed is increased, thereby improving performance of the semiconductor structure.

In forms of a forming method of a semiconductor structure provided in embodiments and implementations of the present disclosure, the source/drain contact materials are formed first, and then partial thicknesses of the source/drain contact materials located in the source/drain connection regions are removed, to form the source/drain contact layers located in the source/drain connection regions and the source/drain plugs located in the source/drain contact regions. Therefore, in embodiments and implementations of the present disclosure, the source/drain plugs and the source/drain contact layers are formed in the same step, which not only simplifies the process, but also omits a process of aligning the source/drain plugs and the source/drain contact layers. Correspondingly, process difficulty in forming the source/drain plugs is reduced, and a process window for forming the source/drain plugs is enlarged. In addition, the source/drain contact structures formed by the source/drain plugs and the source/drain contact layers are an integrated structure, which reduces resistances of the source/drain plugs and the source/drain contact layers, and contact resistances between the source/drain plugs and the source/drain contact layers, and correspondingly improves performance of electrical connection between the source/drain plugs and the source/drain contact layers. Therefore, a back-end-of-line resistance capacitance (RC) delay is alleviated, power consumption is reduced, and a circuit response speed is increased, thereby improving performance of the semiconductor structure.

In some implementations, remaining regions in the gate structures other than the gate contact regions are used as gate spaced regions; and after the base is provided and before the top dielectric layers are formed, the forming method of a semiconductor structure further includes: removing partial thicknesses of gate structures located in the gate spaced regions. Therefore, the gate structures located in the gate contact regions are not etched, and compared with the gate structures in the gate spaced regions, the gate structures in the gate contact regions have higher top surfaces, which reduces a formation height of the gate plugs subsequently, thereby reducing difficulty in forming the gate plugs and enlarging a process window for forming the gate plugs, and further reduces resistances of the gate plugs.

In some implementations, after the base is provided and before the partial thicknesses of gate structures located in the gate spaced regions are removed, the forming method of a semiconductor structure further includes: forming etch stop structures covering the tops of the gate structures in the gate contact regions. The etch stop structures are located on the tops of the gate structures in the gate contact regions, and are further used for pre-occupying a spatial position for forming the gate plugs. In the subsequent process of forming the gate plugs, the gate plugs correspondingly penetrate the etch stop structures. Since the etch stop structures have etching selectivity with the top dielectric layers, the spaced dielectric layers, and the bottom dielectric layers, formation positions of the gate plugs and the etch stop structures are self-aligned, thereby reducing a probability of short-circuiting between the gate plugs and the source/drain contact structures. Moreover, the etch stop structures are further used for playing a role of etch stop in the subsequent process of forming the source/drain contact materials, and preventing the source/drain contact materials from being formed on the gate structures in the gate contact regions and short-circuited to the gate structures, thereby improving reliability of the semiconductor structure.

### BRIEF DESCRIPTION OF THE DRAWINGS

FIG. 1 to FIG. 6 are schematic structural diagrams corresponding to steps in a forming method of a semiconductor structure;

FIG. 7 to FIG. 9 are schematic structural diagrams of one form of a semiconductor structure according to the present disclosure; and

FIG. 10 to FIG. 37 are schematic structural diagrams corresponding to steps in one form of a forming method of a semiconductor structure according to the present disclosure.

### DETAILED DESCRIPTION

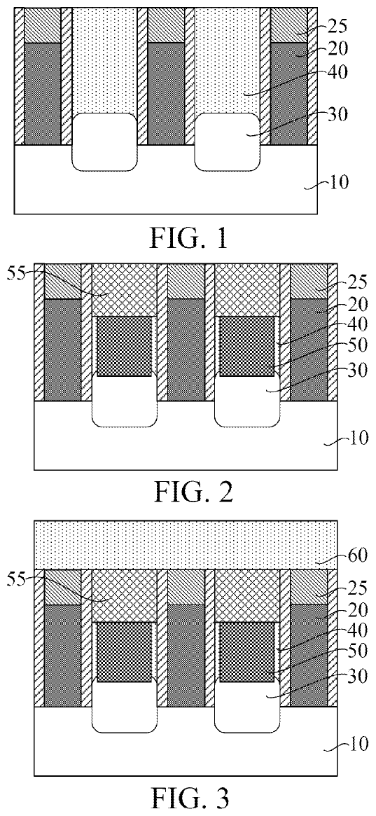

It can be learned from the related art that, at present, performance of a semiconductor structure needs to be improved. Reasons why the performance of a semiconductor structure needs to be improved are now analyzed in combination with a forming method of a semiconductor structure. FIG. 1 to FIG. 6 are schematic structural diagrams corresponding to steps in a forming method of a semiconductor structure.

Referring to FIG. 1, a base 10 is provided, gate structures 20 are formed on the base 10, gate cap layers 25 are formed on top surfaces of the gate structures 20, source/drain doped regions 30 are formed in the base 10 on two sides of the gate structures 20, bottom dielectric layers 40 covering the source/drain doped regions 30 are formed on the base 10 on sides of the gate structures 20, and the bottom dielectric layers 40 expose top surfaces of the gate cap layers 25.

Referring to FIG. 2, source/drain contact layers 50 penetrating the bottom dielectric layers 40 on the tops of the source/drain doped regions 30 are formed, to be in contact with the source/drain doped regions 30; partial thicknesses of the source/drain contact layers 50 are removed, and source/drain cap layers 55 are formed on tops of the remaining source/drain contact layers 50.

Referring to FIG. 3, top dielectric layers 60 are formed on the bottom dielectric layers 40, to cover the source/drain cap layers 55 and the gate cap layers 25.

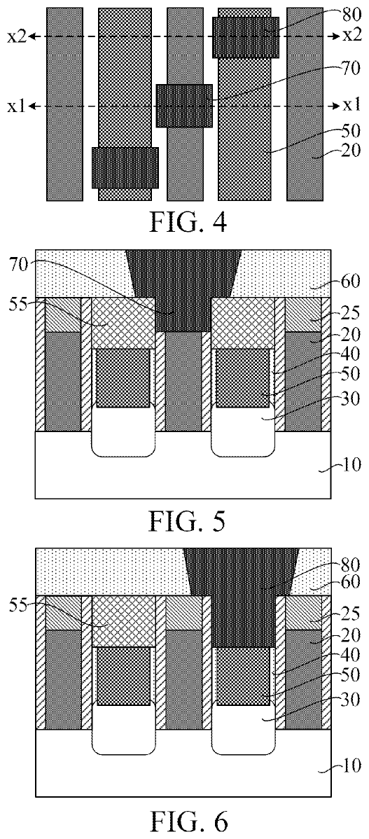

Referring to FIG. 4 to FIG. 6, FIG. 4 is a top view, FIG. 5 is a cross-sectional view of FIG. 4 in an x1 direction, and FIG. 6 is a cross-sectional view of FIG. 4 in an x2-x2 direction. Gate plugs 70 penetrating the gate cap layers 25 on tops of the gate structures 20 and the top dielectric layers 60 are formed, to be in contact with the gate structures 20; and source/drain plugs 80 penetrating the source/drain cap layers 55 on tops of the source/drain contact layers 50 and the top dielectric layers 60 are formed, to be in contact with the source/drain contact layers 50.

In the method, the source/drain contact layers 50 and the source/drain cap layers 55 located on the tops of the source/drain contact layers 50 are formed first, and then the source/drain cap layers 55 are etched to form the source/drain plugs 80 in contact with the source/drain contact layers 50. In the process of forming the source/drain plugs 80, the source/drain plugs 80 need to be aligned with the source/drain contact layers 50, which can easily cause a problem of overlay shift, further easily reduces a process window for forming the source/drain plugs 80 and increases process difficulty in forming the source/drain plugs 80, and can easily cause a large contact resistance between the source/drain plugs 80 and the source/drain contact layers 50, resulting in poor electrical connection performance of the semiconductor structure. In addition, the process procedure of the method is relatively complex.

To address the technical problems, embodiments and implementations of the present disclosure provide a semiconductor structure, where the source/drain contact structures are an integrated structure, and include source/drain plugs penetrating dielectric structure layers of the source/drain contact regions and source/drain contact layers located in dielectric structures of the source/drain connection regions, and top surfaces of the source/drain contact layers are lower than top surfaces of the source/drain plugs. The source/drain contact structures are an integrated structure, which reduces resistances of the source/drain plugs and the source/drain contact layers, and contact resistances between the source/drain plugs and the source/drain contact layers, and correspondingly improves performance of electrical connection between the source/drain plugs and the source/drain contact layers. Therefore, a back-end-of-line resistance capacitance (RC) delay is alleviated, power consumption is reduced, and a circuit response speed is increased, thereby improving performance of the semiconductor structure.

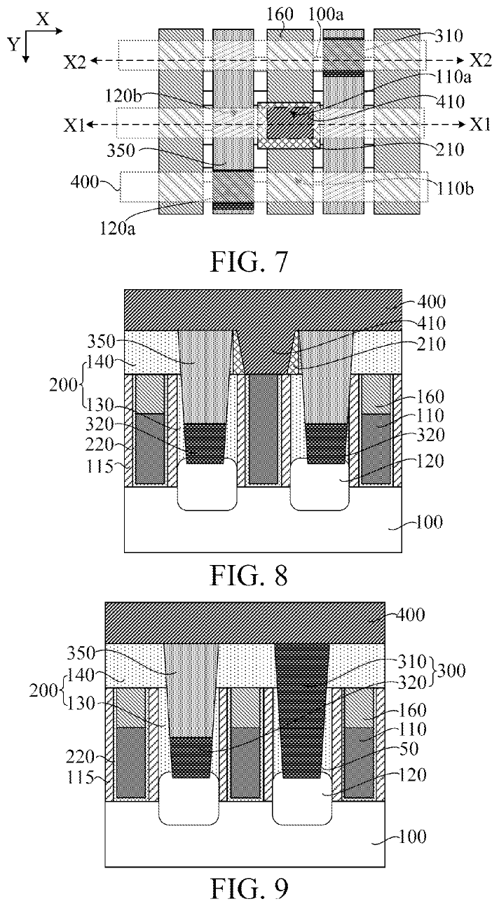

To make the foregoing objectives, features, and advantages of embodiments and implementations of the present disclosure more apparent and easier to understand, specific embodiments and implementations of the present disclosure are described in detail below with reference to the accompanying drawings. FIG. 7 to FIG. 9 are schematic structural diagrams of one form of a semiconductor structure according to the present disclosure. FIG. 7 is a top view, FIG. 8 is a cross-sectional view of FIG. 7 in an X1-X1 direction, and FIG. 9 is a cross-sectional view of FIG. 7 in an X2-X2 direction.

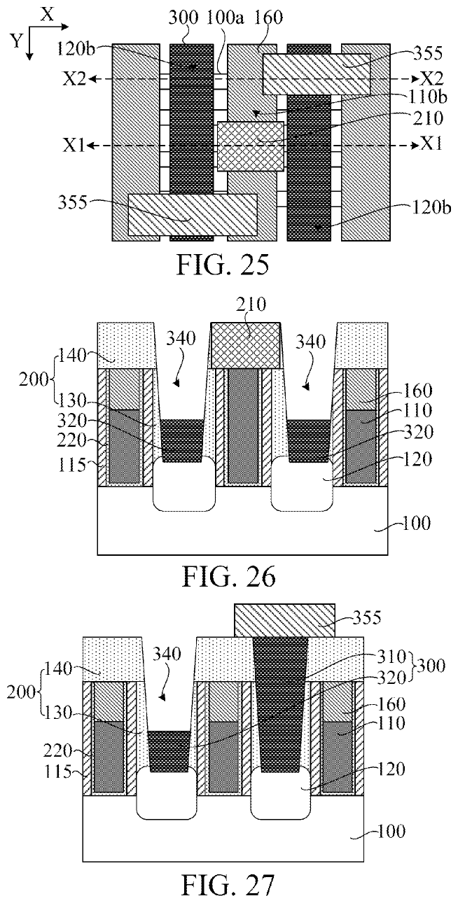

In this form, the semiconductor structure includes: a base 100; a plurality of gate structures 110 arranged discretely on the base 100, where the gate structures 110 include gate contact regions 110a used for contact with gate plugs 410; source/drain doped regions 120, located in the base 100 on two sides of the gate structures 110, where the source/drain doped regions 120 include source/drain contact regions 120a used for contact with source/drain plugs 310, and remaining regions of the source/drain doped regions are used as source/drain connection regions 120b; dielectric structure layers 200, located on the base 100 on sides of the gate structures 110 and covering the source/drain doped regions 120, where the dielectric structure layers 200 further cover tops of the gate structures 110; source/drain contact structures 300, being in contact with the source/drain doped regions 120, where the source/drain contact structures 300 are an integrated structure, and include source/drain plugs 310 penetrating dielectric structure layers 200 of the source/drain contact regions 120a and source/drain contact layers 320 located in dielectric structures 200 of the source/drain connection regions 120b, top surfaces of the source/drain contact layers 320 are lower than top surfaces of the source/drain plugs 310, and the source/drain contact structures 300 and the dielectric structure layers 200 enclose spaced openings 340 (as shown in FIG. 25 and FIG. 26); spaced dielectric layers 350, filling the spaced openings 340; and gate plugs 410, located on tops of the gate structures 110 in the gate contact regions 110a and in contact with the gate structures 110.

The base 100 is used for providing a process platform for forming the semiconductor structure. In this form, the base 100 is used for forming a fin field effect transistor (FinFET). Correspondingly, the base 100 is a three-dimensional base, and includes a substrate (not shown) and fins 100a arranged discretely on the substrate.

The fins 100a are used for providing a conductive channel of a field effect transistor (FET). In this form, the substrate is a silicon substrate, and the fins 100a have the same material as that of the substrate. In other forms, other suitable semiconductor materials may be selected for the substrate and the fins.

In this form, there are a plurality of fins 100a. The plurality of fins 100a extend in a transverse direction (as shown in an X direction in FIG. 7) and are spaced in a longitudinal direction (as shown in a Y direction in FIG. 7). The transverse direction is perpendicular to the longitudinal direction. In this form, the transverse direction and the longitudinal direction are both parallel to a top surface of the base 100.

In other forms, depending on a type of transistor to be formed, the base may alternatively be another type of three-dimensional base. For example, when a gate-all-around (GAA) transistor is formed, the base includes a substrate and a channel structure layer located on the substrate, and the channel structure layer includes one or more channel layers spaced. In some other forms, when a planar FET is formed, the base is correspondingly a planar base.

When a device is in operation, the gate structures 110 are used for controlling on or off of a conductive channel. In this form, the gate structures 110 are located on the substrate. The gate structures 110 span the fins 100a and cover partial top surfaces and partial sidewalls of the fins 100a. The gate structures 110 correspondingly extend in the longitudinal direction.

In this form, the gate structures 110 are metal gate structures, including a work function layer (not shown) and a gate electrode layer (not shown) located on the work function layer. In other forms, according to actual process requirements, the gate structures may be alternatively polysilicon gate structures.

The gate structures 110 in the gate contact regions 110a are used for contact with the gate plugs 410, to lead out the electricity of the gate structures 110. Remaining regions in the gate structures 110 other than the gate contact regions 110a are used as gate spaced regions 110b.

In this form, the semiconductor structure further includes: gate cap layers 160, located between tops of the gate structures 110 in the gate spaced regions 110b and the dielectric structure layers 200; and top surfaces of the gate structures 110 in the gate contact regions 110a are higher than top surfaces of the gate structures 110 in the gate spaced regions 110b.

In this form, compared with the gate structures 110 in the gate spaced regions 110b, the gate structures 110 in the gate contact regions 110a have higher top surfaces, which reduces a height of the gate plugs 410, thereby reducing difficulty in forming the gate plugs 410 and enlarging a process window for forming the gate plugs 410, and further reduces resistances of the gate plugs 410.

The gate cap layers 160 are used for protecting the tops of the gate structures 110 in the process of forming the semiconductor structure, for example, in the process of forming the source/drain contact structures 300, protect the tops of the gate structures 110, to prevent short-circuiting between the source/drain contact structures 300 and the gate structures 110.

The gate cap layers 160 are made of a material that has etching selectivity with the dielectric structure layers 200. The material of the gate cap layers 160 includes one or more of silicon nitride, silicon carbide, silicon carbon nitride, silicon oxycarbonitride, silicon oxynitride, boron nitride, and boron carbon nitride. In an example, the material of the gate cap layers 160 is silicon nitride.

In this form, the semiconductor structure further includes spacers 115 located on the sidewalls of the gate structures 110. The spacers 115 are used for defining a forming region of the source/drain doped regions 120, and are further used for protecting the sidewalls of the gate structures 110. In this form, a material of the spacers 115 includes one or more of silicon nitride, silicon carbon nitride, silicon oxycarbide, silicon carbide, and a low-k dielectric material.

In this form, the gate structures 110 are formed by using a high k last metal gate last process. Therefore, the semiconductor structure further includes high-k gate dielectric layers 220, located between the gate structures 110 and the spacers 115, and between the gate structures 110 and the base 100. The high-k gate dielectric layers 220 are used for electrically isolating the gate structures 110 from a channel. A material of the high-k gate dielectric layers 220 is a high-k dielectric material.

The source/drain doped regions 120 are used for providing a carrier source. In this form, when the device is in operation, the source/drain doped regions 120 are further used for providing stress for the channel, to improve the carrier mobility. In this form, the source/drain doped regions 120 are located in the fins 100a on two sides of the gate structures 110.

In this form, when an NMOS transistor is formed, the source/drain doped regions 120 include stress layers doped with N-type ions; and when a PMOS transistor is formed, the source/drain doped regions 120 include stress layers doped with P-type ions.

The source/drain doped regions 120 of the source/drain contact regions 120a are used for contact with the source/drain plugs 310, to lead out the electricity of the source/drain doped regions 120. The source/drain doped regions 120 of the source/drain connection regions 120b are used for contact with the source/drain contact layers 320, and the source/drain contact layers 320 are used for implementing electrical connection between the source/drain doped regions 120 located in the plurality of fins 100a.

The dielectric structure layers 200 are used for implementing isolation between adjacent devices, and are further used for implementing electrical isolation between the source/drain plugs 310 and the gate plugs 410.

In this form, the dielectric structure layers 200 are laminated structures. The dielectric structure layers 200 include: bottom dielectric layers 130, located on the base 100 on the sides of the gate structures 110 and covering the source/drain doped regions 120; and top dielectric layers 140, located on the bottom dielectric layers 130.

The bottom dielectric layers 130 are used for implementing isolation between adjacent devices. A material of the bottom dielectric layers 130 is a dielectric material, for example, one or more of silicon oxide, silicon nitride, silicon oxynitride, silicon oxycarbide, silicon carbon nitride, and silicon oxycarbonitride. The top dielectric layers 140 are used for implementing electrical isolation between the gate plugs 410 and the source/drain contact structures 300. A material of the top dielectric layers 140 is a dielectric material, for example, one or more of silicon oxide, silicon nitride, silicon oxynitride, silicon oxycarbide, silicon carbon nitride, silicon oxycarbonitride, a low-k dielectric material, and an ultra-low-k dielectric material.

In this form, the semiconductor structure further includes: etch stop structures 210, located on the tops of the gate structures 110 in the gate contact regions 110a; the dielectric structure layers 200 cover sidewalls of the etch stop structures 210; and the gate plugs 410 penetrate the etch stop structures 210.

In this form, the top surfaces of the gate structures 110 in the gate spaced regions 110b are lower than the top surfaces of the gate structures 110 in the gate contact regions 110a, which is because partial thicknesses of the gate structures 110 in the gate spaced regions 110b are further removed in the process of forming the semiconductor structure. The etch stop structures 210 are used as masks for removing the partial thicknesses of the gate structures 110 in the gate spaced regions 110b. In addition, the etch stop structures 210 are located on the tops of the gate structures 110 in the gate contact regions 110a, and are further used for pre-occupying a spatial position for forming the gate plugs 410. Moreover, the etch stop structures 210 are further used for playing a role of etch stop in the process of forming the source/drain contact structures 300, preventing the source/drain contact structures 300 from being formed on the gate structures 110 in the gate contact regions 110a and short-circuited to the gate structures 110.

In this form, the etch stop structures 210 further extend to cover partial top surfaces of the bottom dielectric layers 130 located on two sides of the gate structures 110, thereby increasing an area of the etch stop structures 210, and further improving effects of the etch stop structures 210 as etching masks and for etch stop.

In this form, the top dielectric layers 140 cover sidewalls of the etch stop structures 210, and the top surfaces of the top dielectric layers 140 are flush with the top surfaces of the etch stop structures 210.

Therefore, the etch stop structures 210 are made of a material that has etching selectivity with the dielectric structure layers 200, and the material of the etch stop structures 210 has an etching selectivity ratio with the material of the gate cap layers 160. The material of the etch stop structures 210 includes one or more of AlN, Al₂O₃, SiCN, SiON, SiOC, AlON, Si, Ge, C, and SiO₂. In an example, the material of the etch stop structures 210 is aluminum oxide.

The thicknesses of the etch stop structures 210 should not be too small, or otherwise the effects of the etch stop structures 210 as etching masks and for etch stop may be poor; and the thicknesses of the etch stop structure 210 should not be too large, or otherwise heights of the source/drain plugs 310 may be too large, which may increase the difficulty in forming the source/drain contact structures 300, and may further cause the resistances of the source/drain contact structures 300 to be too high. Therefore, in this form, the thicknesses of the etch stop structures 210 are 50% to 150% of the thicknesses of the gate cap layers 160.

In an example, the thicknesses of the etch stop structures 210 are the same as the thicknesses of the gate cap layers 160. Specifically, the thicknesses of the etch stop structures 210 are 3 nanometers to 10 nanometers.

The source/drain contact structures 300 are used for leading out the electricity of the source/drain doped regions 120. The source/drain contact layers 320 are used for implementing electrical connection between the source/drain doped regions 120 located in the plurality of fins 100a, and the source/drain plugs 310 are used for implementing electrical connection with the metal interconnect lines.

The spaced openings 340 (as shown in FIG. 27) are used for providing a spatial position for forming the spaced dielectric layers.

In this form, the source/drain contact structures 300 are an integrated structure, including source/drain plugs 310 with higher top surfaces and source/drain contact layers 320 with lower top surfaces, which is because the step of forming the source/drain contact structures 300 includes: forming source/drain contact materials, and then removing partial thicknesses of the source/drain contact materials located in the source/drain connection regions 120b. Therefore, the source/drain plugs 310 and the source/drain contact layers 320 are formed in the same step, which not only simplifies the process, but also omits a process of aligning the source/drain plugs 310 and the source/drain contact layers 320. Correspondingly, process difficulty in forming the source/drain plugs 310 is reduced, and a process window for forming the source/drain plugs 310 is enlarged. In addition, the source/drain contact structures 300 formed by the source/drain plugs 310 and the source/drain contact layers 320 are an integrated structure, which reduces resistances of the source/drain plugs 310 and the source/drain contact layers 320, and contact resistances between the source/drain plugs 310 and the source/drain contact layers 320, and correspondingly improves performance of electrical connection between the source/drain plugs 310 and the source/drain contact layers 320. Therefore, a back-end-of-line resistance capacitance (RC) delay is alleviated, power consumption is reduced, and a circuit response speed is increased, thereby improving performance of the semiconductor structure.

In this form, the top surfaces of the source/drain contact layers 320 are lower than the top surfaces of the source/drain plugs 310, which reduces heights of the top surfaces of the source/drain contact layers 320, and therefore reduces a probability of short-circuiting between the gate plugs 410 and the source/drain contact layers 320, thereby improving the reliability of the semiconductor structure.

In this form, the top surfaces of the source/drain contact layers 320 are lower than the top surfaces of the bottom dielectric layers 130. Specifically, in an example, the top surfaces of the source/drain contact layers 320 are lower than the top surfaces of the gate structures 110 in the gate spaced regions 110b, thereby further reducing the heights of the top surfaces of the source/drain contact layers 320 to increase a distance between the top surfaces of the source/drain contact layers 320 and bottom surfaces of the gate plugs 410, and significantly reducing the probability of short-circuiting between the gate plugs 410 and the source/drain contact layers 320.

In this form, the source/drain contact structures 300 are bar-shaped structures, and the source/drain contact structures 300 extend in the longitudinal direction (as shown in the Y direction in FIG. 7). The direction perpendicular to the longitudinal direction is the transverse direction (as shown in the X direction in FIG. 7).

A material of the source/drain contact structures 300 is a conductive material. The source/drain contact structures 300 are single-layer or multi-layer structures. In an example, the source/drain contact structures 300 include main contact structures (not shown) and source/drain contact diffusion stop layers (not shown) located on sidewalls and at bottoms of the main contact structures.

The source/drain contact diffusion stop layers are used for improving adhesion between the main contact structures and the dielectric structure layers 200, and the source/drain contact diffusion stop layers are further used for preventing materials of the main contact structures from diffusing into the dielectric structure layers 200, thereby alleviating a problem of electro-migration (EM). In addition, the source/drain contact diffusion stop layers are further used for preventing impurities such as carbon atoms and oxygen atoms in the dielectric structure layers 200 from diffusing into the main contact structures, which improves the reliability of the semiconductor structure.

In this form, a material of the main contact structures includes one or more of W, Co, Ru, Cu, and Al, and a material of the source/drain contact diffusion stop layers includes one or more of TiN, Ti, TaN, and Ta.

The spaced dielectric layers 350 are used for filling the spaced openings 340, to provide a planar surface for the process, and the spaced dielectric layers 350 are further used for implementing isolation between adjacent devices.

A material of the spaced dielectric layers 350 is a dielectric material, for example, one or more of silicon oxide, silicon nitride, silicon oxynitride, silicon oxycarbide, silicon carbon nitride, silicon oxycarbonitride, a low-k dielectric material, and an ultra-low-k dielectric material.

The gate plugs 410 are used for leading out the electricity of the gate structures 110, to implement electrical connection between the gate structures 110 and an external circuit or another interconnect structure.

In this form, the gate plugs 410 are located above the gate structures 110 in an active area (AA), and the gate plugs 410 are correspondingly contact over active gates (COAG), which saves an area of a chip, thereby further reducing the chip size.

In this form, compared with the gate structures 110 in the gate spaced regions 110b, the gate structures 110 in the gate contact regions 110a have higher top surfaces, which reduces a height of the gate plugs 410, thereby reducing difficulty in forming the gate plugs 410 and enlarging a process window for forming the gate plugs 410, and further reduces resistances of the gate plugs 410. In particular, the gate plugs 410 are contact over active gates, and it is more difficult to form the gate plugs 410. This form helps to significantly reduce the difficulty of the COAG process. Specifically, the heights of the gate plugs 410 are the same as the thicknesses of the top dielectric layers 140.

In this form, the gate plugs 410 penetrate the etch stop structures 210.

In this form, a material of the gate plugs 410 is a conductive material. The gate plugs 410 are single-layer or multi-layer structures. In an example, the gate plugs 410 include main gate plugs (not shown), and gate plug diffusion stop layers (not shown) located at bottoms and on sidewalls of the main gate plugs.

The gate plug diffusion stop layers are used for improving adhesion between the main gate plugs and the etch stop structures 210; and the gate plug diffusion stop layers are further used for preventing materials of the main gate plugs from diffusing into the etch stop structures 210 or the dielectric structure layers 200, thereby alleviating the problem of electro-migration. In addition, the gate plug diffusion stop layers are further used for preventing impurities such as carbon atoms and oxygen atoms in the etch stop structures 210 or the dielectric structure layers 200 from diffusing into the main gate plugs, which improves the reliability of the semiconductor structure.

In this form, a material of the main gate plugs includes one or more of W, Co, Ru, Cu, and Al, and a material of the gate plug diffusion stop layers includes one or more of TiN, Ti, TaN, and Ta.

In this form, the step of forming the gate plugs 410 includes: forming gate contact holes; and forming the gate plugs 410 in the gate contact holes. There is etching selectivity between the material of the etch stop structures 210 and the material of the dielectric structure layers 200. Therefore, in a process of forming the gate contact holes, there is a high etching selectivity ratio between the etch stop structures 210 and the top dielectric layers 140, and between the etch stop structures 210 and the bottom dielectric layers 130, so that the top dielectric layers 140 or the bottom dielectric layers 130 are not easily etched mistakenly. Correspondingly, self-aligned etching can be implemented, process difficulty in forming the gate contact holes is reduced, a process window for forming the gate contact holes is increased, shapes and positions of the gate contact holes can be precisely controlled, and the gate contact holes do not easily expose the source/drain plugs 310.

Correspondingly, shapes, positions, and cross-sectional profiles of the gate plugs 410 can be controlled, and a probability of bridging between the gate plugs 410 and the source/drain plugs 310 is low, which improves the reliability of the semiconductor structure. In particular, in this form, the gate plugs 410 are contact over active gates, and distances between the gate plugs 410 and the source/drain plugs 310 are smaller. This form helps to significantly reduce the probability of bridging between the gate plugs 410 and the source/drain plugs 310.

It should be noted that, in this form, the gate plugs 410 penetrate the etch stop structures 210, and partial etch stop structures 210 are retained on the sidewalls of the gate plugs 410. In other forms, according to an actual process, in a process of forming the gate plugs, the etch stop structures may alternatively be completely removed, and the sidewalls of the gate plugs are correspondingly in contact with the top dielectric layers.

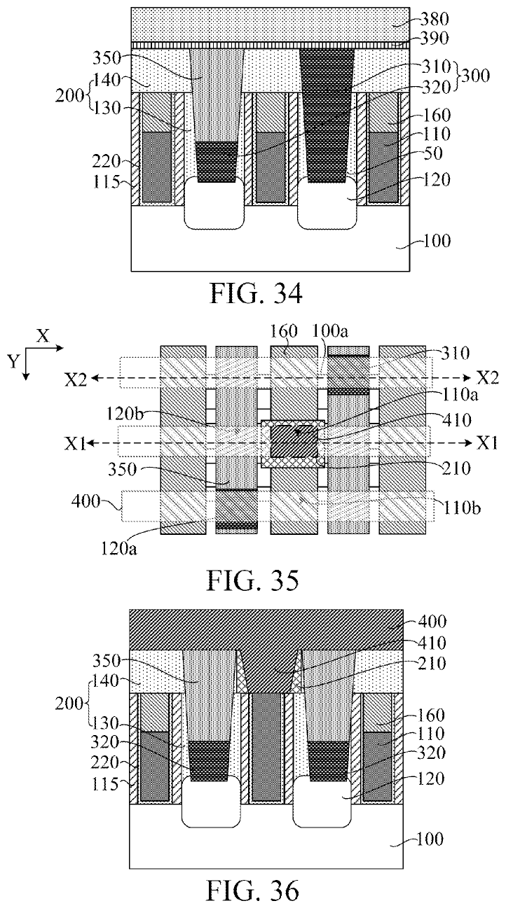

In this form, the semiconductor structure further includes: interconnect dielectric layers 380 (referring to FIG. 33 and FIG. 34), located on the dielectric structure layers 200 and covering the spaced dielectric layers 350 and the top surfaces of the source/drain plugs 310; and metal interconnect lines 400, penetrating the interconnect dielectric layers 380, where the metal interconnect lines 400 extend in the transverse direction and are spaced in the longitudinal direction, and the metal interconnect lines 400 are correspondingly in contact with the gate plugs 410 and the source/drain plugs 310 respectively.

The interconnect dielectric layers 380 are used for implementing electrical isolation between the metal interconnect lines 400. The interconnect dielectric layers 380 are correspondingly inter-metal dielectric (IMD) layers, and a material of the interconnect dielectric layers 380 is a dielectric material. For the related description of the material of the interconnect dielectric layers 380, reference may be made to the corresponding description of the top dielectric layers 140 above, and details are not described again herein.

The metal interconnect lines 400 are used for electrically connecting the gate plugs 410 and the source/drain plugs 310 to external circuits.

In this form, the metal interconnect lines 400 and the gate plugs 410 are an integrated structure. Therefore, contact resistances between the gate plugs 410 and the metal interconnect lines 400 are reduced, and performance of electrical connection between the gate plugs 410 and the metal interconnect lines 400 is improved, thereby optimizing the performance of the semiconductor structure.

In this form, a material of the metal interconnect lines 400 is the same as the material of the gate plugs 410. It should be noted that, in this form, for ease of illustration and description, only the dielectric structure layers 200, the interconnect dielectric layers 380, the high-k gate dielectric layers 220, and the spacers 115 are shown in the cross-sectional view.

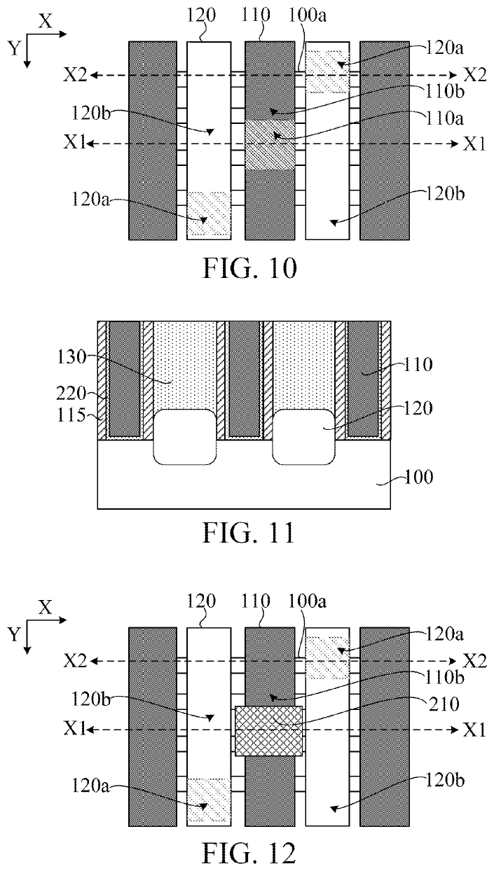

Accordingly, the present disclosure further provides a forming method of a semiconductor structure. FIG. 10 to FIG. 37 are schematic structural diagrams corresponding to steps in one form of a forming method of a semiconductor structure according to the present disclosure. The forming method of a semiconductor structure of this form is described in detail below with reference to the accompanying drawings.

Referring to FIG. 10 and FIG. 11, FIG. 10 is a top view, and FIG. 11 is a cross-sectional view of FIG. 10 in the X1-X1 direction. A base 100 is provided, where a plurality of discrete gate structures 110 are formed on the base 100, the gate structures 110 include gate contact regions 110a used for contact with gate plugs, source/drain doped regions 120 are formed in the base 100 on two sides of the gate structures 110, the source/drain doped regions 120 include source/drain contact regions 120a used for contact with source/drain plugs, remaining regions of the source/drain doped regions are used as source/drain connection regions 120b, and bottom dielectric layers 130 are formed on the base 100 on sides of the gate structures 110 and cover the source/drain doped regions 120.

The base 100 is used for providing a process platform for subsequent processes. In this form, the base 100 is used for forming a FinFET. Correspondingly, the base 100 is a three-dimensional base, and includes a substrate (not shown) and fins 100a arranged discretely on the substrate.

The fins 100a are used for providing a conductive channel of a field effect transistor (FET). In this form, the substrate is a silicon substrate, and the fins 100a have the same material as that of the substrate. In other forms, other suitable semiconductor materials may be selected for the substrate and the fins.

In this form, there are a plurality of fins 100a. The plurality of fins 100a extend in a transverse direction (as shown in an X direction in FIG. 10) and are spaced in a longitudinal direction (as shown in a Y direction in FIG. 10). The transverse direction is perpendicular to the longitudinal direction. In this form, the transverse direction and the longitudinal direction are both parallel to a top surface of the base 100.

In other forms, depending on a type of transistor to be formed, the base may alternatively be another type of three-dimensional base. For example, when a gate-all-around (GAA) transistor is formed, the base includes a substrate and a channel structure layer located on the substrate, and the channel structure layer includes one or more channel layers spaced. In some other forms, when a planar FET is formed, the base is correspondingly a planar base.

When a device is in operation, the gate structures 110 are used for controlling on or off of a conductive channel. In this form, the gate structures 110 are located on the substrate. The gate structures 110 span the fins 100a and cover partial top surfaces and partial sidewalls of the fins 100a. The gate structures 110 correspondingly extend in the longitudinal direction.

In this form, the gate structures 110 are metal gate structures, including a work function layer (not shown) and a gate electrode layer (not shown) located on the work function layer. In other forms, according to actual process requirements, the gate structures may be alternatively polysilicon gate structures.

The gate structures 110 in the gate contact regions 110a are used for contact with the gate plugs subsequently, to lead out the electricity of the gate structures 110. Remaining regions in the gate structures 110 other than the gate contact regions 110a are used as gate spaced regions 110b.

In this form, spacers 115 are further formed on the sidewalls of the gate structure 110. The spacers 115 are used for defining a forming region of the source/drain doped regions 120, and are further used for protecting the sidewalls of the gate structures 110. In this form, a material of the spacers 115 includes one or more of silicon nitride, silicon carbon nitride, silicon oxycarbide, silicon carbide, and a low-k dielectric material.

In this form, the gate structures 110 are formed by using a high k last metal gate last process. High-k gate dielectric layers 220 are further formed between the gate structures 110 and the spacers 115, and between the gate structures 110 and the base 100. The high-k gate dielectric layers 220 are used for electrically isolating the gate structures 110 from a channel. A material of the high-k gate dielectric layers 220 is a high-k dielectric material.

The source/drain doped regions 120 are used for providing a carrier source. In this form, when the device is in operation, the source/drain doped regions 120 are further used for providing stress for the channel, to improve the carrier mobility. In this form, the source/drain doped regions 120 are located in the fins 100a on two sides of the gate structures 110.

In this form, when an NMOS transistor is formed, the source/drain doped regions 120 include stress layers doped with N-type ions; and when a PMOS transistor is formed, the source/drain doped regions 120 include stress layers doped with P-type ions.

The source/drain doped regions 120 of the source/drain contact regions 120a are used for contact with the subsequent source/drain plugs, to lead out the electricity of the source/drain doped regions 120. The source/drain contact layers in contact with the source/drain doped regions 120 of the source/drain connection regions 120b are formed subsequently, and the source/drain contact layers are used for implementing electrical connection between the source/drain doped regions 120 located on the plurality of fins 100a.

The bottom dielectric layers 130 are used for implementing isolation between adjacent devices. A material of the bottom dielectric layers 130 is a dielectric material, for example, one or more of silicon oxide, silicon nitride, silicon oxynitride, silicon oxycarbide, silicon carbon nitride, and silicon oxycarbonitride.

It should be noted that, in this form, for ease of illustration and description, only the bottom dielectric layers 140, the high-k gate dielectric layers 220, and the spacers 115 are shown in the cross-sectional view.

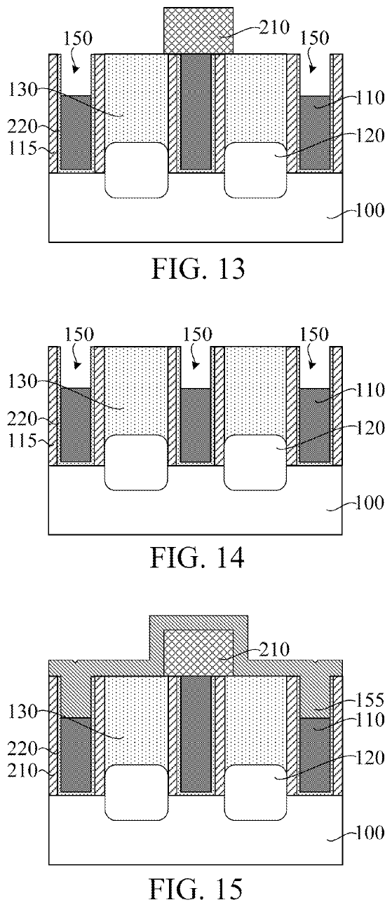

Referring to FIG. 12 to FIG. 14, FIG. 12 is a top view, FIG. 13 is a cross-sectional view of FIG. 12 in the X1-X1 direction, and FIG. 14 is a cross-sectional view of FIG. 12 in the X2-X2 direction. After the base 100 is provided, the forming method further includes forming etch stop structures 210 covering the tops of the gate structures 110 of the gate contact regions 110a.

The subsequent steps further include: removing partial thicknesses of gate structures 110 located in the gate spaced regions 110b, forming top dielectric layers on the bottom dielectric layers 130; and forming source/drain contact materials penetrating the bottom dielectric layers 130 on tops of the source/drain doped regions 120 and the top dielectric layers, to be in contact with the source/drain doped regions 120.

The etch stop structures 210 are used as masks for removing the partial thicknesses of the gate structures 110 in the gate spaced regions 110b. In addition, the etch stop structures 210 are located on the tops of the gate structures 110 in the gate contact regions 110a, and are further used for pre-occupying a spatial position for forming the gate plugs. Moreover, the etch stop structures 210 are further used for playing a role of etch stop in the subsequent process of forming the source/drain contact materials, and preventing the source/drain contact materials from being formed on the gate structures 110 in the gate contact regions 110a and short-circuited to the gate structures 110.

In this form, the etch stop structures 210 further extend to cover partial top surfaces of the bottom dielectric layers 130 located on two sides of the gate structures 110, thereby increasing an area of the etch stop structures 210, and improving effects of the etch stop structures 210 as etching masks and for etch stop.

Therefore, the etch stop structures 210 are made of a material that has etching selectivity with the bottom dielectric layers 130 and the top dielectric layers. Moreover, after the partial thicknesses of gate structures 110 located in the gate spaced regions 110b are subsequently removed, the step of forming gate cap layers on the tops of the gate spaced regions 110b is further included. The forming the gate cap layers includes a process of etching the material of the gate cap layers. Correspondingly, the material of the etch stop structures 210 needs to have an etching selectivity ratio with the material of the gate cap layers.

The material of the etch stop structures 210 includes one or more of AlN, Al₂O₃, SiCN, SiON, SiOC, AlON, Si, Ge, C, and SiO₂. In an example, the material of the etch stop structures 210 is Al₂O₃.

The thicknesses of the etch stop structures 210 should not be too small, or otherwise the effects of the etch stop structures 210 as etching masks and for etch stop may be poor; and the thicknesses of the etch stop structure 210 should not be too large, or otherwise heights of the subsequent source/drain contact materials may be too large, which may increase the difficulty in forming the source/drain contact materials, and may further cause the resistances of the source/drain contact structures to be too high. Therefore, in this form, the thicknesses of the etch stop structures 210 are 50% to 150% of the thicknesses of the subsequent gate cap layers.

In an example, the thicknesses of the etch stop structures 210 are the same as the thicknesses of the subsequent gate cap layers. Specifically, the thicknesses of the etch stop structures 210 are 3 nanometers to 20 nanometers.

In this form, the etch stop structures 210 are located on the tops of the gate structures 110 in the gate contact regions 110a, and are used for pre-occupying a spatial position for forming the gate plugs. Therefore, positions of the etch stop structures 210 correspond to positions of the gate plugs. The etch stop structures 210 may be formed using a mask used when the gate plugs are formed. Therefore, there is no need to use an additional mask, costs are reduced, and compatibility with existing processes can be further improved.

In an example, the step of forming the etch stop structures 210 includes: forming etch stop materials (not shown) on the bottom dielectric layers 130, to cover the gate structures 110; patterning the etch stop materials, and retaining the etch stop materials on the tops of the gate structures 110 in the gate contact regions 110a to be used as the etch stop structures 210. The etch stop materials are patterned by using the mask used when the gate plugs are formed.

Referring to FIG. 12 to FIG. 19, the forming method of a semiconductor structure further includes: removing partial thicknesses of gate structures 110 located in the gate spaced regions 110b, so that the remaining gate structures 110 and the bottom dielectric layers 140 enclose gate grooves 150; and forming gate cap layers 160 in the gate grooves 150.

The gate grooves 150 are used for providing a spatial position for forming the gate cap layers 160.

In this form, the partial thicknesses of gate structures 110 located in the gate spaced regions 110b are removed, so that the gate structures 110 located in the gate contact regions 110a are not etched. Compared with the gate structures 110 in the gate spaced regions 110b, the gate structures 110 in the gate contact regions 110a have higher top surfaces, which reduces a height of the gate plugs subsequently, thereby reducing difficulty in forming the gate plugs and enlarging a process window for forming the gate plugs, and further reduces resistances of the gate plugs.

Specifically, the partial thicknesses of gate structures 110 located in the gate spaced regions 110b are removed by using the etch stop structures 210 as masks.

In this form, the partial thicknesses of gate structures 110 located in the gate spaced regions 110b are removed by using a dry etching process. The material of the gate structures 110 includes a metal material. The dry etching process is easy to etch the metal material, and the dry etching process can implement a higher etching selectivity ratio and etching profile controllability, to precisely control an etching thickness of the gate structures 110.

The gate cap layers 160 are used for protecting the tops of the gate structures 110 in the subsequent process, for example, in the process of forming the source/drain contact structures, protect the tops of the gate structures 110, to prevent short-circuiting between the source/drain contact structures and the gate structures 110.

Therefore, the gate cap layers 160 are made of a material that has etching selectivity with the bottom dielectric layers 130, and meanwhile, the material of the gate cap layers 160 also has etching selectivity with the etch stop structures 210, to ensure that the etch stop structures 210 can be retained in the process of forming the gate cap layers 160.

The material of the gate cap layers 160 includes one or more of silicon nitride, silicon carbide, silicon carbon nitride, silicon oxycarbonitride, silicon oxynitride, boron nitride, and boron carbon nitride. In an example, the material of the gate cap layers 160 is silicon nitride.

The step of forming the gate cap layers 160 of this form is described in detail below with reference to the accompanying drawings.

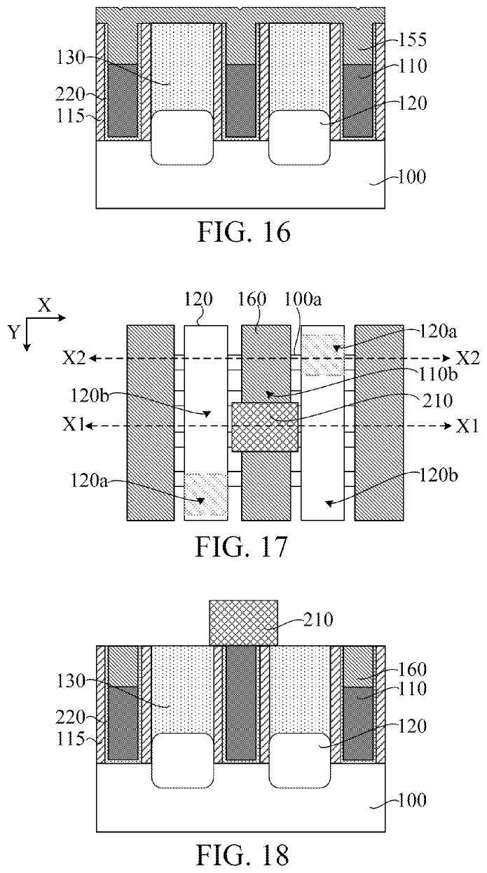

As shown in FIG. 15 and FIG. 16, FIG. 15 is a cross-sectional view based on FIG. 13, and FIG. 16 is a cross-sectional view based on FIG. 14. Gate cap material layers 155 filling the gate grooves 150 and covering the bottom dielectric layers 130 and the etch stop structures 210 are formed. The gate cap material layers 155 are formed by using a deposition process (for example, a chemical vapor deposition process, or an atomic layer deposition process).

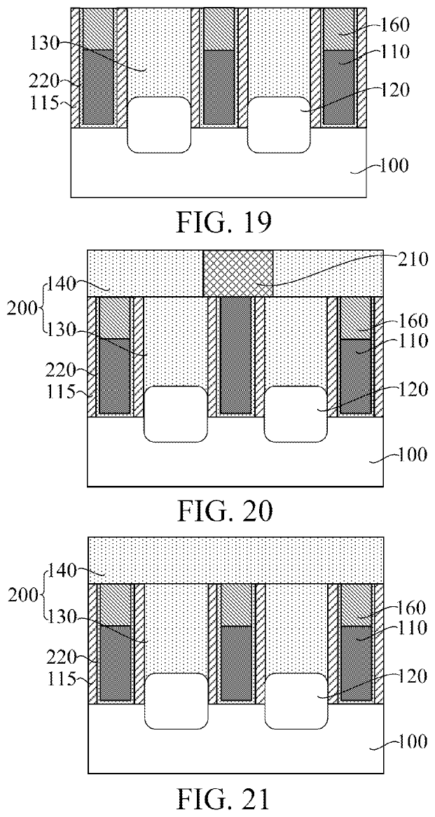

As shown in FIG. 17 to FIG. 19, FIG. 17 is a top view, FIG. 18 is a cross-sectional view of FIG. 17 in the X1-X1 direction, and FIG. 19 is a cross-sectional view of FIG. 17 in the X2-X2 direction. The gate cap material layers 155 located on top surfaces of the bottom dielectric layers 130 and on the etch stop structures 210 are removed by using an etching process, remaining gate cap material layers 155 located in the gate grooves 150 being used as the gate cap layers 160.

In this form, the gate cap material layers 155 have an etching selectivity ratio with the etch stop structures 210, so that a probability that the etch stop structures 210 are etched mistakenly by the etching process is low, and the etch stop structures 210 can be retained. Specifically, the etching process includes an isotropic dry etching process, thereby implementing isotropic etching, and further removing the gate cap material layers 155 located on the bottom surfaces and sidewalls of the etch stop structures 210 and on the top surfaces of the bottom dielectric layers 130.

Referring to FIG. 20 and FIG. 21, FIG. 20 is a cross-sectional view based on FIG. 18, and FIG. 21 is a cross-sectional view based on FIG. 19. The top dielectric layers 140 are formed on the bottom dielectric layers 130.

The bottom dielectric layers 130 and the top dielectric layers 140 are used for forming the dielectric structure layers 200.

The top dielectric layers 140 are used for implementing electrical isolation between the gate plugs and the source/drain contact structures. A material of the top dielectric layers 140 is a dielectric material, for example, one or more of silicon oxide, silicon nitride, silicon oxynitride, silicon oxycarbide, silicon carbon nitride, silicon oxycarbonitride, a low-k dielectric material, and an ultra-low-k dielectric material.

In this form, the top dielectric layers 140 cover the sidewalls of the etch stop structures 210. In this form, for ease of illustration and description, only the top dielectric layers 140 are shown in the cross-sectional view.

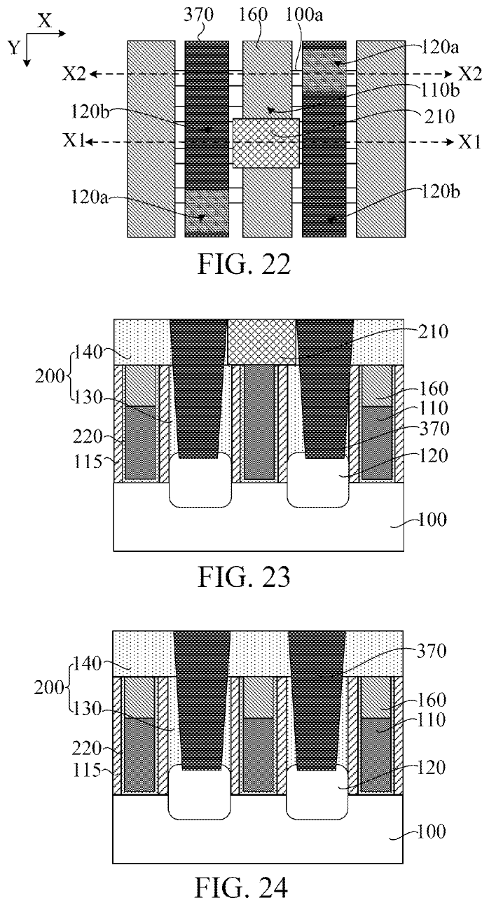

Referring to FIG. 22 to FIG. 24, FIG. 22 is a top view, FIG. 23 is a cross-sectional view of FIG. 22 in the X1-X1 direction, and FIG. 24 is a cross-sectional view of FIG. 22 in the X2-X2 direction. The source/drain contact materials 370 penetrating the bottom dielectric layers 130 on tops of the source/drain doped regions 120 and the top dielectric layers 140, to be in contact with the source/drain doped regions 120.

The source/drain contact materials 370 are used for forming the source/drain contact structures, to lead out the electricity of the source/drain doped regions 120.

In this form, the source/drain contact materials 370 are bar-shaped structures, and the source/drain contact materials 370 extend in the longitudinal direction.

Therefore, a material of the source/drain contact materials 370 is a conductive material. The source/drain contact materials 370 are single-layer or multi-layer structures. In an example, the source/drain contact materials 370 include main contact materials (not shown) and source/drain contact diffusion stop materials (not shown) located on sidewalls and at bottoms of the main contact materials.

In this form, the main contact materials include one or more of W, Co, Ru, Cu, and Al, and the source/drain contact diffusion stop materials include one or more of TiN, Ti, TaN, and Ta.

In this form, the step of forming the source/drain contact materials 370 includes: forming source/drain contact openings (not shown) penetrating the dielectric structure layers 200, to expose the source/drain doped regions 120; and forming the source/drain contact materials 370 in the source/drain contact openings.

Referring to FIG. 25 to FIG. 27, FIG. 25 is a top view, FIG. 26 is a cross-sectional view of FIG. 25 in the X1-X1 direction, and FIG. 27 is a cross-sectional view of FIG. 25 in the X2-X2 direction. After the source/drain contact materials 370 are formed and before the partial thicknesses of the source/drain contact materials 370 located in the source/drain connection regions 120b are removed, the forming method further includes: forming hard mask layers 355 on the tops of the source/drain contact materials 370 in the source/drain contact region 120a.

The hard mask layers 355 are used as masks for subsequently removing the partial thicknesses of the source/drain contact materials 370 located in the source/drain connection regions 120b. Positions of the hard mask layers 355 correspond to formation positions of the source/drain plugs.

Therefore, the hard mask layers 355 are made of a material that has etching selectivity with the source/drain contact materials 370, to ensure an etching mask effect of the hard mask layers 355. In this form, the material of the hard mask layers 355 includes one or more of AlN, Al₂O₃, SiCN, SiON, SiOC, AlON, Si, Ge, C, and SiO₂. In an example, the material of the hard mask layer 355 is AlN.

In this form, positions of the hard mask layers 355 correspond to the formation positions of the source/drain plugs. Therefore, the hard mask layer 355 may be formed by using a mask used when the source/drain plugs are formed. Correspondingly, there is no need to use an additional mask, thereby reducing costs.

In an example, the step of forming the hard mask layers 355 includes: forming hard mask material layers (not shown) on the top dielectric layers 140, to cover the source/drain contact materials 370; patterning the hard mask material layers, and retaining the hard mask material layers located in the source/drain contact regions 120a to be used as the hard mask layers 355. The hard mask material layers are patterned by using the mask used when the source/drain plugs are formed.

Still referring to FIG. 25 to FIG. 27, FIG. 25 is a top view, FIG. 26 is a cross-sectional view of FIG. 25 in the X1-X1 direction, and FIG. 27 is a cross-sectional view of FIG. 25 in the X2-X2 direction. The partial thicknesses of the source/drain contact materials 370 located in the source/drain connection regions 120b are removed, where remaining source/drain contact materials 370 located in the source/drain connection regions 120b are used as source/drain contact layers, the source/drain contact materials 370 located in the source/drain contact regions 120a are used as source/drain plugs 310, the source/drain plugs 310 and the source/drain contact layers 320 are used for forming source/drain contact structures 300, and the source/drain contact structures 300 enclose spaced openings 340 with the bottom dielectric layers 130 and the top dielectric layers 140.

The source/drain contact structures 300 are used for leading out the electricity of the source/drain doped regions 120. The source/drain contact layers 320 are used for implementing electrical connection between the source/drain doped regions 120 located in the plurality of fins 100a, and the source/drain plugs 310 are used for implementing electrical connection with the metal interconnect lines formed subsequently.

The spaced openings 340 are used for providing a spatial position for forming the spaced dielectric layers.

In this form, the source/drain contact materials 370 are formed first, and then partial thicknesses of the source/drain contact materials 370 located in the source/drain connection regions 120b are removed, to form the source/drain contact layers 320 located in the source/drain connection regions 120b and the source/drain plugs 310 located in the source/drain contact regions 120a. Therefore, the source/drain plugs 310 and the source/drain contact layers 320 are formed in the same step, which not only simplifies the process, but also omits a process of aligning the source/drain plugs 310 and the source/drain contact layers 320, and prevents a problem of overlay shift between the source/drain plugs 310 and the source/drain contact layers 320. Correspondingly, process difficulty in forming the source/drain plugs 310 is reduced, and a process window for forming the source/drain plugs 310 is enlarged. In addition, the source/drain contact structures 300 formed by the source/drain plugs 310 and the source/drain contact layers 320 are an integrated structure, which reduces resistances of the source/drain plugs 310 and the source/drain contact layers 320, and contact resistances between the source/drain plugs 310 and the source/drain contact layers 320, and correspondingly improves performance of electrical connection between the source/drain plugs 310 and the source/drain contact layers 320. Therefore, a back-end-of-line resistance capacitance (RC) delay is alleviated, power consumption is reduced, and a circuit response speed is increased, thereby improving performance of the semiconductor structure.

Correspondingly, the top surfaces of the source/drain contact layers 320 are lower than the top surfaces of the source/drain plugs 310.

In this form, the partial thicknesses of the source/drain contact materials 370 located in the source/drain connection regions 120b are removed, which reduces heights of the top surfaces of the source/drain contact layers 320, and therefore reduces a probability of short-circuiting between the gate plugs and the source/drain contact layers 320 subsequently, thereby improving the reliability of the semiconductor structure.

In this form, the top surfaces of the source/drain contact layers 320 are lower than the top surfaces of the bottom dielectric layers 130. Specifically, in an example, the top surfaces of the source/drain contact layers 320 are lower than the top surfaces of the gate structures 110 in the gate spaced regions 110b, thereby further reducing the heights of the top surfaces of the source/drain contact layers 320 to increase a distance between the top surfaces of the source/drain contact layers 320 and bottom surfaces of the gate plugs, and significantly reducing the probability of short-circuiting between the gate plugs and the source/drain contact layers 320.

In this form, after the partial thicknesses of the source/drain contact materials 370 located in the source/drain connection regions 120b are removed, the source/drain contact structures 300 correspondingly include main contact structures (not shown) and source/drain contact diffusion stop layers (not shown) located on sidewalls and at bottoms of the main contact structures.

The source/drain contact diffusion stop layers are used for improving adhesion between the main contact structures and the dielectric structure layers 200, and the source/drain contact diffusion stop layers are further used for preventing materials of the main contact structures from diffusing into the dielectric structure layers 200, thereby alleviating a problem of electro-migration. In addition, the source/drain contact diffusion stop layers are further used for preventing impurities such as carbon atoms and oxygen atoms in the dielectric structure layers 200 from diffusing into the main contact structures, which improves the reliability of the semiconductor structure.

For the related description of the material of the source/drain contact structures 300, reference may be made to the detailed description of the material of the source/drain contact materials 370 above, as the details are not described again herein.

In this form, the partial thicknesses of the source/drain contact materials 370 located in the source/drain connection regions 120b are removed by using the hard mask layers 355 as masks.

In this form, the partial thicknesses of the source/drain contact materials 370 located in the source/drain connection regions 120b are removed by using a dry etching process. Specifically, the dry etching process is an anisotropic dry etching process, and the anisotropic dry etching process is characterized by anisotropic etching, to precisely control a removal thickness of the source/drain contact materials 370, and improve cross-sectional profile quality of the spaced openings 340. An etching gas used in the dry etching process includes an etching gas such as SF₆ that is used for etching metal materials.

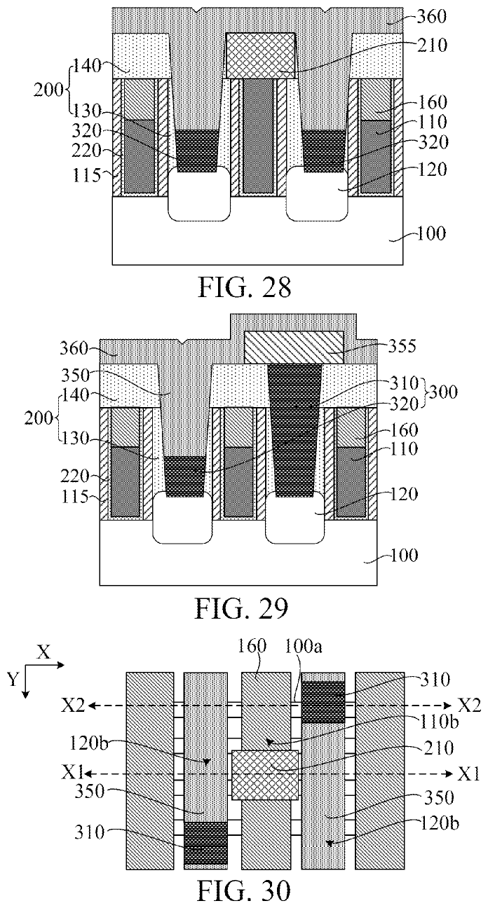

In this form, the gate structures 110 and the source/drain contact structures 300 both extend in the longitudinal direction (as shown in the Y direction in FIG. 25). The direction perpendicular to the longitudinal direction is the transverse direction (as shown in the X direction in FIG. 25). Referring to FIG. 28 to FIG. 32, the spaced openings 340 are filled with spaced dielectric layers 350.

The spaced dielectric layers 350 are used for filling the spaced openings 340, to provide a planar surface for the subsequent process, and the spaced dielectric layers 350 are further used for implementing isolation between adjacent devices.

A material of the spaced dielectric layers 350 is a dielectric material, for example, one or more of silicon oxide, silicon nitride, silicon oxynitride, silicon oxycarbide, silicon carbon nitride, silicon oxycarbonitride, a low-k dielectric material, and an ultra-low-k dielectric material.

In this form, the step of forming the spaced dielectric layers 340 includes the following steps.

As shown in FIG. 28 and FIG. 29, FIG. 28 is a cross-sectional view based on FIG. 26, and FIG. 29 is a cross-sectional view based on FIG. 27. The spaced openings 340 are filled with dielectric materials 360, and the dielectric materials 360 are further formed on the top dielectric layers 140. In this form, the dielectric materials 360 are further formed on the hard mask layers 355.

In this form, a process of filling the spaced openings 340 with the dielectric materials 360 includes one or more of a flowable chemical vapor deposition (FCVD) process, a spin coating process, and an atomic layer deposition process.

In an example, the dielectric materials 360 are formed by using the FCVD process. The FCVD process has good filling capability, which is suitable for filling an opening of a high aspect ratio, improves filling quality of the dielectric materials 360 in the spaced openings 340, reduces a probability that defects such as holes are formed in the dielectric materials 360, and correspondingly improves forming quality of the spaced dielectric layers.

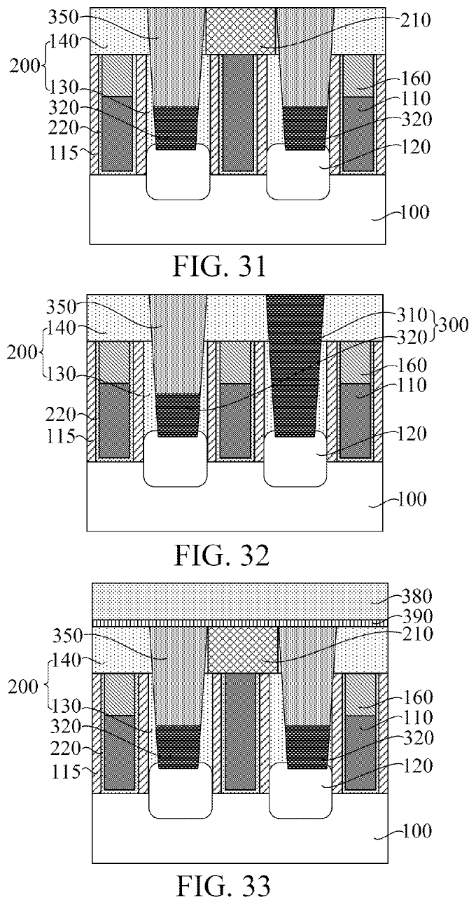

As shown in FIG. 30 to FIG. 32, FIG. 30 is a top view, FIG. 31 is a cross-sectional view of FIG. 30 in the X1-X1 direction, and FIG. 32 is a cross-sectional view of FIG. 30 in the X2-X2 direction. The dielectric materials 360 higher than top surfaces of the top dielectric layers 140 are removed by using a planarization process, remaining dielectric materials 360 located in the spaced openings 340 being used as the spaced dielectric layers 350.

In this form, the forming method further includes: removing the hard mask layers 355 in the process of removing the dielectric materials 360 higher than the top surfaces of the top dielectric layers 140, thereby simplifying the process steps and improving process compatibility.

In this form, the planarization process includes a chemical mechanical planarization process. The chemical mechanical planarization process is a global planarization process, which implements overall planarization of various materials with different characteristics, so that the dielectric materials 360 higher than the top surfaces of the top dielectric layers 140 and the hard mask layers 355 can be removed in the same step, and planarity between the top surfaces of the spaced dielectric layers 350, the top dielectric layers 140, and the source/drain plugs 310 is further improved.

Referring to FIG. 33 and FIG. 34, FIG. 33 is a cross-sectional view based on FIG. 31, and FIG. 34 is a cross-sectional view based on FIG. 32. After the spaced dielectric layers 350 are formed, the forming method further includes: forming interconnect dielectric layers 380 on the top dielectric layers 140 and the spaced dielectric layers 350, to cover the source/drain plugs 310.

The subsequent step further includes: forming metal interconnect lines in the interconnect dielectric layers 380, the interconnect dielectric layers 380 being used for implementing electrical isolation between the metal interconnect lines.

The interconnect dielectric layers 380 are correspondingly inter-metal dielectric (IMD) layers, and a material of the interconnect dielectric layers 380 is a dielectric material. For the related description of the material of the interconnect dielectric layers 380, reference may be made to the corresponding description of the top dielectric layers 140 above, and details are not described again herein.

It should be noted that, in this form, before the interconnect dielectric layers 380 are formed, the forming method further includes: forming etch stop layers 390 on the top dielectric layers 140 and the spaced dielectric layers 350.

The etch stop layers 390 are used for temporarily defining etch stop positions in the subsequent process of forming the gate plugs, to improve consistency between etch positions, and reduce damage to the source/drain plugs 310.

In this form, for ease of illustration and description, only the interconnect dielectric layers 380 and the etch stop layers 390 are shown in the cross-sectional view.

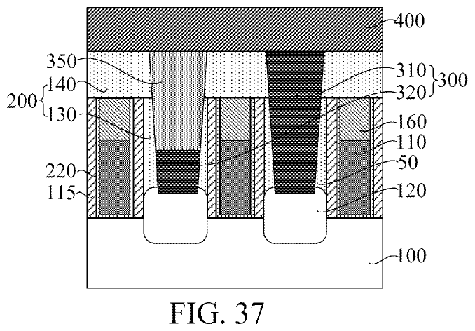

Referring to FIG. 35 to FIG. 37, FIG. 35 is a top view, FIG. 36 is a cross-sectional view of FIG. 35 in the X1-X1 direction, and FIG. 37 is a cross-sectional view of FIG. 35 in the X2-X2 direction. After the spaced dielectric layers 350 are formed, gate plugs 410 penetrating the top dielectric layers 140 above the gate contact regions 110a are formed, to be in contact with tops of the gate structures 110 in the gate contact regions 110a.

The gate plugs 410 are used for leading out the electricity of the gate structures 110, to implement electrical connection between the gate structures 110 and an external circuit or another interconnect structure.

In this form, the gate plugs 410 are in contact with the gate structures 110 in the active area, and the gate plugs 410 are correspondingly contact over active gates (COAG), which saves an area of a chip, thereby further reducing the chip size.

In this form, before the top dielectric layers 140 are formed, the partial thicknesses of gate structures 110 located in the gate spaced regions 110b are removed, while the gate structures 110 located in the gate contact regions 110a are not etched, so that the gate structures 110 in the gate contact regions 110a have higher top surfaces, which reduces a height of the gate plugs 410, thereby reducing difficulty in forming the gate plugs 410 and enlarging a process window for forming the gate plugs 410, and further reduces resistances of the gate plugs 410. In particular, in this form, the gate plugs 410 are contact over active gates, and it is more difficult to form the gate plugs 410. This form helps to significantly reduce the difficulty of the COAG process.

Specifically, the heights of the gate plugs 410 are the same as the thicknesses of the top dielectric layers 140. In this form, the gate plugs 410 penetrate the etch stop structures 210.

In this form, a material of the gate plugs 410 is a conductive material. The gate plugs 410 are single-layer or multi-layer structures. In an example, the gate plugs 410 include main gate plugs (not shown), and gate plug diffusion stop layers (not shown) located at bottoms and on sidewalls of the main gate plugs.

The gate plug diffusion stop layers are used for improving adhesion between the main gate plugs and the etch stop structures 210; and the gate plug diffusion stop layers are further used for preventing materials of the main gate plugs from diffusing into the etch stop structures 210 or the dielectric structure layers 200, thereby alleviating the problem of electro-migration. In addition, the gate plug diffusion stop layers are further used for preventing impurities such as carbon atoms and oxygen atoms in the etch stop structures 210 or the dielectric structure layers 200 from diffusing into the main gate plugs, which improves the reliability of the semiconductor structure.

In this form, a material of the main gate plugs includes one or more of W, Co, Ru, Cu, and Al, and a material of the gate plug diffusion stop layers includes one or more of TiN, Ti, TaN, and Ta.

In this form, the step of forming the gate plugs 410 includes: forming gate contact holes (not shown) penetrating the etch stop structures 210, to expose the tops of the gate structures 110 in the gate contact regions 110a; and forming the gate plugs 410 in the gate contact holes.

There is etching selectivity between the material of the etch stop structures 210 and the material of the top dielectric layers 140 or the bottom dielectric layers 130. Therefore, in a process of forming the gate contact holes, there is a high etching selectivity ratio between the etch stop structures 210 and the top dielectric layers 140, and between the etch stop structures 210 and the bottom dielectric layers 130, so that the top dielectric layers 140 or the bottom dielectric layers 130 are not easily etched mistakenly. Correspondingly, self-aligned etching can be implemented, process difficulty in forming the gate contact holes is reduced, a process window for forming the gate contact holes is increased, shapes and positions of the gate contact holes can be precisely controlled, and the gate contact holes do not easily expose the source/drain plugs 310.

Correspondingly, after the gate plugs 410 are formed in the gate contact holes, shapes, positions, and cross-sectional profiles of the gate plugs 410 can be controlled, and a probability of bridging between the gate plugs 410 and the source/drain plugs 310 is low, which improves the reliability of the semiconductor structure. Correspondingly, the gate plugs 410 penetrate the etch stop structures 210. In particular, in this form, the gate plugs 410 are contact over active gates, and distances between the gate plugs 410 and the source/drain plugs 310 are smaller. This form helps to significantly reduce the probability of bridging between the gate plugs 410 and the source/drain plugs 310.

It should be noted that, in this form, the gate plugs 410 penetrate the etch stop structures 210, and partial etch stop structures 210 are retained on the sidewalls of the gate plugs 410. In other forms, according to an actual process, in a process of forming the gate plugs, the etch stop structures may alternatively be completely removed, and the sidewalls of the gate plugs are correspondingly in contact with the top dielectric layers.

In this form, the gate plugs 410 are formed after the interconnect dielectric layers 380 are formed.

In the step of forming the gate plugs 410, the forming method of a semiconductor structure further includes: forming, in the interconnect dielectric layers 380, metal interconnect lines 400 extending in the transverse direction (as shown in the X direction in FIG. 35) and spaced in the longitudinal direction (as shown in the Y direction in FIG. 35), the metal interconnect lines 400 being correspondingly in contact with the gate plugs 410 and the source/drain plugs 310 respectively.

The metal interconnect lines 400 are used for electrically connecting the gate plugs 410 and the source/drain plugs 310 to external circuits. In this form, the metal interconnect lines 400 and the gate plugs 410 are formed in the same step, so that the processes of forming the metal interconnect lines 400 and the gate plugs 410 are integrated, thereby improving process integration and process compatibility, and simplifying the process steps.

In this form, the step of forming the metal interconnect lines 400 and the gate plugs 410 includes:

forming a plurality of interconnect trenches (not shown) extending in the transverse direction and penetrating the interconnect dielectric layers 380, the interconnect trenches, on a projection plane parallel to the base 100, respectively spanning tops of the source/drain plugs 310 and the tops of the gate structures 110 in the gate contact regions 110a; forming gate contact holes (not shown) in the top dielectric layers 140 above the tops of the gate structures 110, to be in communication with the interconnect trenches; and filling the gate contact holes and the interconnect trenches with conductive materials, to form the gate plugs 410 located in the gate contact holes and the metal interconnect lines 400 located in the interconnect trenches.

Correspondingly, in this form, in the process of forming the interconnect trenches, an extension direction of the interconnect trenches is perpendicular to extension directions of the gate structures 110 and the source/drain contact structures 300, and the interconnect trenches respectively expose the tops of the source/drain plugs 310 and the tops of the etch stop structures 210.

In this form, in the same step, the gate contact holes and the interconnect trenches are filled with the conductive materials, to form the gate plugs 410 and the metal interconnect lines 400, where the gate plugs 410 and the metal interconnect lines 400 are correspondingly an integrated structure. Therefore, contact resistances between the gate plugs 410 and the metal interconnect lines 400 are reduced, and performance of electrical connection between the gate plugs 410 and the metal interconnect lines 400 is improved, thereby optimizing the performance of the semiconductor structure. Correspondingly, a material of the metal interconnect lines 400 is the same as the material of the gate plugs 410. In this form, the metal interconnect lines 400 further penetrate the etch stop layers 390.

Although the present disclosure is disclosed above, the present disclosure is not limited thereto. A person skilled in the art can make various changes and modifications without departing from the spirit and the scope of the present disclosure. Therefore, the protection scope of the present disclosure should be subject to the scope defined by the claims.

What is claimed is:

1. A semiconductor structure, comprising:
a base;
a plurality of gate structures arranged discretely on the base, wherein the gate structures comprise gate contact regions configured to contact with gate plugs;
source/drain doped regions, located in the base on two sides of the gate structures, wherein the source/drain doped regions comprise source/drain contact regions configured to contact with source/drain plugs, where remaining regions of the source/drain doped regions are configured for use as source/drain connection regions;
dielectric structure layers, located on the base on sides of the gate structures and covering the source/drain doped regions, wherein the dielectric structure layers further cover tops of the gate structures;
source/drain contact structures, in contact with the source/drain doped regions, wherein the source/drain contact structures are an integrated structure, and comprise source/drain plugs penetrating dielectric structure layers of the source/drain contact regions and source/drain contact layers located in dielectric structures of the source/drain connection regions, top surfaces of the source/drain contact layers are lower than top surfaces of the source/drain plugs, and the source/drain contact structures and the dielectric structure layers enclose spaced openings;
spaced dielectric layers, filling the spaced openings; and
gate plugs, located on tops of the gate structures in the gate contact regions and in contact with the gate structures.

2. The semiconductor structure according to claim 1, wherein the dielectric structure layers comprise: bottom dielectric layers, located on the base on the sides of the gate structures and covering the source/drain doped regions; and top dielectric layers, located on the bottom dielectric layers.

3. The semiconductor structure according to claim 2, wherein the top surfaces of the source/drain contact layers are lower than top surfaces of the bottom dielectric layers.

4. The semiconductor structure according to claim 1, wherein the semiconductor structure further comprises:
gate cap layers, located between tops of the gate structures in gate spaced regions and the dielectric structure layers; and
top surfaces of the gate structures in the gate contact regions are higher than top surfaces of the gate structures in the gate spaced regions.

5. The semiconductor structure according to claim 4, wherein the top surfaces of the source/drain contact layers are lower than the top surfaces of the gate structures in the gate spaced regions.

6. The semiconductor structure according to claim 4, wherein:
the semiconductor structure further comprises: etch stop structures, located on the tops of the gate structures in the gate contact regions;
the dielectric structure layers cover sidewalls of the etch stop structures; and
the gate plugs penetrate the etch stop structures.

7. The semiconductor structure according to claim 6, wherein a material of the etch stop structures comprises at least one of AlN, Al₂O₃, SiCN, SiON, SiOC, AlON, Si, Ge, C, or SiO₂.

8. The semiconductor structure according to claim 6, wherein thicknesses of the etch stop structures are 50% to 150% of thicknesses of the gate cap layers.

9. The semiconductor structure according to claim 1, wherein:
the gate structures and the source/drain contact structures extend both in a longitudinal direction, and a direction perpendicular to the longitudinal direction is a transverse direction; and
the semiconductor structure further comprises:
interconnect dielectric layers, located on the dielectric structure layers and covering the spaced dielectric layers and the top surfaces of the source/drain plugs; and
metal interconnect lines, penetrating the interconnect dielectric layers, wherein the metal interconnect lines extend in the transverse direction and are spaced in the longitudinal direction, and the metal interconnect lines are correspondingly in contact with the gate plugs and the source/drain plugs respectively.

10. The semiconductor structure according to claim 9, wherein the metal interconnect lines and the gate plugs are an integrated structure.

11. A forming method of a semiconductor structure, comprising:
providing a base, wherein a plurality of discrete gate structures are formed on the base, the gate structures comprise gate contact regions used for contact with gate plugs, source/drain doped regions are formed in the base on two sides of the gate structures, the source/drain doped regions comprise source/drain contact regions used for contact with source/drain plugs, remaining regions of the source/drain doped regions are used as source/drain connection regions, and bottom dielectric layers are formed on the base on sides of the gate structures and cover the source/drain doped regions;
forming top dielectric layers on the bottom dielectric layers;
forming source/drain contact materials penetrating the bottom dielectric layers on tops of the source/drain doped regions and the top dielectric layers, to be in contact with the source/drain doped regions;
removing partial thicknesses of the source/drain contact materials located in the source/drain connection regions, wherein remaining source/drain contact materials located in the source/drain connection regions are used as source/drain contact layers, the source/drain contact materials located in the source/drain contact regions are used as source/drain plugs, the source/drain plugs and the source/drain contact layers are used for forming source/drain contact structures, and the source/drain contact structures enclose spaced openings with the bottom dielectric layers and the top dielectric layers; filling the spaced openings with spaced dielectric layers; and
forming, after forming the spaced dielectric layers, gate plugs penetrating the top dielectric layers above the gate contact regions, to be in contact with tops of the gate structures in the gate contact regions.

12. The forming method of a semiconductor structure according to claim 11, wherein:
remaining regions in the gate structures other than the gate contact regions are used as gate spaced regions; and
after the base is provided and before the top dielectric layers are formed, the forming method of a semiconductor structure further comprises:
removing partial thicknesses of gate structures located in the gate spaced regions, so that the remaining gate structures and the bottom dielectric layers enclose gate grooves; and
forming gate cap layers in the gate grooves.

13. The forming method of a semiconductor structure according to claim 12, wherein after the base is provided and before the partial thicknesses of gate structures located in the gate spaced regions are removed, the forming method of a semiconductor structure further comprises:
forming etch stop structures covering the tops of the gate structures in the gate contact regions;
removing the partial thicknesses of gate structures located in the gate spaced regions by using the etch stop structures as masks;
covering, by the top dielectric layers, sidewalls of the etch stop structures in the process of forming the top dielectric layers; and
penetrating, by the gate plugs, the etch stop structures in the step of forming the gate plugs.

14. The forming method of a semiconductor structure according to claim 13, wherein the step of forming the gate cap layers comprises:
forming gate cap material layers filling the gate grooves and covering the bottom dielectric layers and the etch stop structures; and
removing the gate cap material layers located on top surfaces of the bottom dielectric layers and on the etch stop structures using an etching process, where remaining gate cap material layers located in the gate grooves are used as the gate cap layers.

15. The forming method of a semiconductor structure according to claim 13, wherein in the step of forming the etch stop structures, the etch stop structures further extend to cover partial top surfaces of the bottom dielectric layers located on the two sides of the gate structures.

16. The forming method of a semiconductor structure according to claim 11, wherein after the source/drain contact materials are formed and before the partial thicknesses of the source/drain contact materials located in the source/drain connection regions are removed, the forming method of a semiconductor structure further comprises:
forming hard mask layers on tops of the source/drain contact materials of the source/drain contact regions; and
removing the partial thicknesses of the source/drain contact materials located in the source/drain connection regions using the hard mask layers as masks.

17. The forming method of a semiconductor structure according to claim 16, wherein:
the step of forming the spaced dielectric layers comprises:
filling the spaced openings with dielectric materials, the dielectric materials being further formed on the top dielectric layers; and
removing the dielectric materials higher than top surfaces of the top dielectric layers using a planarization process, where remaining dielectric materials located in the spaced openings are used as the spaced dielectric layers; and
the forming method of a semiconductor structure further comprises: removing the hard mask layers in the process of removing the dielectric materials higher than the top surfaces of the top dielectric layers.

18. The forming method of a semiconductor structure according to claim 17, wherein a process of filling the spaced openings with the dielectric materials comprises at least one of a flowable chemical vapor deposition process, a spin coating process, or an atomic layer deposition process.

19. The forming method of a semiconductor structure according to claim 11, wherein in the step of forming the source/drain contact structures, top surfaces of the source/drain contact layers are lower than the top surfaces of the bottom dielectric layers.

20. The forming method of a semiconductor structure according to claim 12, wherein in the step of forming the source/drain contact structures, top surfaces of the source/drain contact layers are lower than top surfaces of the gate structures in the gate spaced regions.

21. The forming method of a semiconductor structure according to claim 11, wherein:
the gate structures and the source/drain contact structures extend both in a longitudinal direction, and a direction perpendicular to the longitudinal direction is a transverse direction;
after the spaced dielectric layers are formed and before the gate plugs are formed, the forming method of a semiconductor structure further comprises: forming interconnect dielectric layers on the top dielectric layers and the spaced dielectric layers, to cover the source/drain plugs; and forming the gate plugs after the interconnect dielectric layers are formed; and
in the step of forming the gate plugs, the forming method of a semiconductor structure further comprises: forming, in the interconnect dielectric layers, metal interconnect lines extending in the transverse direction and spaced in the longitudinal direction, the metal interconnect lines being correspondingly in contact with the gate plugs and the source/drain plugs respectively.

22. The forming method of a semiconductor structure according to claim 21, wherein the step of forming the metal interconnect lines and the gate plugs comprises:
forming a plurality of interconnect trenches extending in the transverse direction and penetrating the interconnect dielectric layers, the interconnect trenches, on a projection plane parallel to the base, respectively spanning tops of the source/drain plugs and the tops of the gate structures in the gate contact regions;
forming gate contact holes in the top dielectric layers above the tops of the gate structures, to be in communication with the interconnect trenches; and
filling the gate contact holes and the interconnect trenches with conductive materials, to form the gate plugs located in the gate contact holes and the metal interconnect lines located in the interconnect trenches.
